(19) United States
(12) Patent Application Publication
(10) Pub. No.: US 2007/0284142 A1
(43) Pub. Date: Dec. 13, 2007

(54) EMI/RFI FINGER CLIP GASKET

(75) Inventor: Reginald Jonker, Corona, CA (US)

Correspondence Address: HUFFMAN LAW GROUP, P.C., 1900 MESA AVE., COLORADO SPRINGS, CO, 80906, US

(73) Assignee: DOT HILL SYSTEMS CORPORATION, Carlsbad, CA (US)

(21) Appl. No.: 11/423,109

(22) Filed: Jun. 8, 2006

(51) Int. Cl. H05K 9/00

(52) U.S. Cl. 174/354

(57) ABSTRACT

An elongated EMI/RFI grounding and shielding structure is formed from a resiliently deflectable, electrically conductive material and has a longitudinally spaced series of specially configured finger sections interdigitated with spring sections. Each finger structure has a domed central body portion, a first end portion with an inwardly curved, generally hook-shaped configuration, and an opposite second end portion having a generally planar outer flange end portion extending outwardly from the body and being offset therefrom by a transverse jog section. The grounding structure is operatively attached to and captively retained on an electrically conductive wall, such as a wall of an electronic component housing, by inserting the first and second finger end portions respectively into spaced series of first and second cutout openings in the wall.

### BACKGROUND OF THE INVENTION

The present invention generally relates to EMI/RFI shielding and, in a representatively illustrated embodiment thereof, more particularly provides a specially designed EMI/RFI finger clip structure useable to conveniently and efficiently provide and maintain an electrical grounding path between separable facing portions of, for example, nested electronic device enclosures..

Radio frequency (RF) and electromagnetic interference (EMI) are important design considerations in the production of various types of electronic apparatus. For example EMI waves from outside the apparatus have the potential to adversely affect the performance of components within the interior of the apparatus. Additionally, various regulatory agencies impose limits on the frequency and levels of EMI signals that may be outwardly generated from the interior of the electronic apparatus.

To control these potential EMI problems the various pieces of an electronics package enclosure are typically made of an electrically conductive material, such as sheet metal, and are coupled to one another. By coupling all pieces of the cover to one another, the entire electronics package enclosure can be effectively coupled to ground to form an EMI barrier around the internal electrical components. Simply fastening the pieces of a cover together it normally not sufficient to ensure electrical conductivity over the anticipated range of operating temperatures and conditions. Internal and external temperature variations may cause some portions of the electronics enclosure to expand or contract at different rates, thereby producing gaps or increasing electrical resistance between pieces of the enclosure.

A conventional approach to these potential grounding problems has been to utilize various types of conductive gaskets, clips, or springs placed between pieces of an enclosure structure to maintain a positive electrical conductivity path between such pieces. EMI gaskets, clips, or springs are typically compressible and are designed to deflect with enough spring force to positively maintain electrical grounding contact with the conductive surfaces of mating pieces of an electronics apparatus enclosure structure. Portions of one of these grounding structures are typically inserted into and retained within cutout openings in a wall section of one of the facing enclosure pieces, with the balance of the grounding structure being positioned and resiliently deflected between the enclosure pieces.

A widely utilized EMI/RFI resilient grounding clip structure has a generally “C”-shaped configuration with identical, inwardly bent opposite retaining end portions which are inserted into a spaced pair of the enclosure wall cutout openings to retain the clip on the enclosure wall and position a domed central portion of the clip in a spaced relationship with a surface portion of the enclosure wall. Various problems, limitations and disadvantages are commonly associated with this conventional “C”-shaped grounding clip configuration, and include grounding contact inefficiencies and potential difficulty in installing the clip(s) on the enclosure wall. Additionally, these conventionally configured clips have a tendency after installation thereof to leave sizeable gaps in the enclosure wall cutout openings through which EMI energy can readily enter and exit the interior of the enclosure. In view of the foregoing it can be readily be seen that it would be desirable to provide an EMI/RFI grounding clip structure that eliminated or at least substantially reduced these problems, limitations and disadvantages of grounding clips having the conventional configuration generally described above.

### SUMMARY OF THE INVENTION

In carrying out principles of the present invention, in accordance with representatively illustrated embodiments thereof, electrical grounding apparatus is provided for securement to an electrically conductive wall structure having spaced first and second openings therein. The grounding apparatus, which is useable to form an electrical grounding path between two adjacent electrically conductive wall structures in a manner providing EMI shielding therefor, comprises a resiliently deflectable finger clip structure having a generally strip-shaped electrically conductive body with a longitudinally bent central portion and differently shaped first and second end sections respectively sized and configured to be received and retained in the first and second wall structure openings. The first end section has an outer end portion extending inwardly toward the second end section in a first direction, and the second end section has an outer end portion extending in the first direction away from the first end section.

Preferably, the first end section has a generally hooked configuration with the outer end portion of the first end section underlying part of the central body portion and being sloped toward the second end section and away from the central body portion, representatively at an angle of approximately two degrees. The outer end portion of the second end section is offset from the central body portion by a jog section extending generally transversely to the outer end portion of the second end section, such outer end portion being sloped outwardly and toward the central body portion at an angle of approximately one degree. Illustratively, the generally strip-shaped body of the finger clip structure has a substantially constant width along its width.

The electrical grounding apparatus, when operatively secured to its associated wall structure, is resiliently deflectable from a relaxed position to a compressed position in which a part of the body, including the second end section thereof, substantially blocks the second wall structure opening to thereby at least substantially lessen the inward and outward transmission of EMI energy therethrough.

According to another aspect of the present invention, a resiliently deflectable, electrically conductive EMI/RFI finger clip gasket structure is provided and has an elongated, laterally bent body portion with opposite first and second side edges and longitudinally interdigitated series of spring sections and the aforementioned finger clip structures, the lengths of such finger clip structures extending transversely to the length of the gasket body portion. Preferably, the gasket body portion has transverse slots disposed therein in the juncture areas between the interdigitated spring and finger clip segments. The first and second end sections of the finger clips are respectively insertable into parallel rows of first and second wall structure openings to operatively mount the gasket structure. When the gasket structure is resiliently compressed toward the wall structure the second finger end sections, together with adjacent portions of the body, are caused to substantially entirely block the second wall structure openings.

According to a further aspect thereof, the present invention also provides electronic apparatus representatively in the form of an electrically conductive component housing having an outer wall portion in which the rows of first and second openings are disposed and operatively and respectively receive the first and second gasket finger end sections. Illustratively, the gasket structure is mounted on the outer side of the outer wall portion, with the outer end portions of the first and second finger end sections extending along the inner side of the outer wall portion. The gasket body portion is movable along the outer side of the outer wall portion toward and away from the first openings, with the finger clip jog sections being cooperatively engageable with peripheral portions of the second openings in a manner preventing the outer end portions of both the first and second finger clip end sections from passing outwardly through their associated wall portion openings.

### BRIEF DESCRIPTION OF THE DRAWINGS

FIG. 1 is a perspective view of a specially configured EMI/RFI finger clip gasket structure embodying principles of the present invention;

FIG. 2 is an enlarged scale perspective view of a single finger clip portion of the overall structure;

FIG. 3 is a cross-sectional view through the finger clip portion taken along line 3-3 of FIG. 2;

FIG. 4 is a plan view of an outer side of an outer wall section of an electronic component housing having formed therein two parallel series of rectangular cutout openings sized to receive and captively retain outer end sections of the finger portions of the gasket structure;

FIG. 5 is a view similar to that in FIG. 4, but with single and multiple clip embodiments of the gasket structure being operatively installed on the outer side of the outer wall section of the electronic component housing;

FIG. 6 is a view similar to that in FIG. 5 but showing the inner side of the outer wall section of the electronic component housing;

FIG. 7 is an enlarged scale cross-sectional view taken along line 7-7 of FIG. 5 through the gasket and wall structures with the gasket structure being in a relaxed condition; and

FIG. 8 is a view similar to that in FIG. 7 but with the gasket structure being held in a compressed condition by a wall section of an outer housing into which the electronic component housing has been representatively inserted.

### DETAILED DESCRIPTION

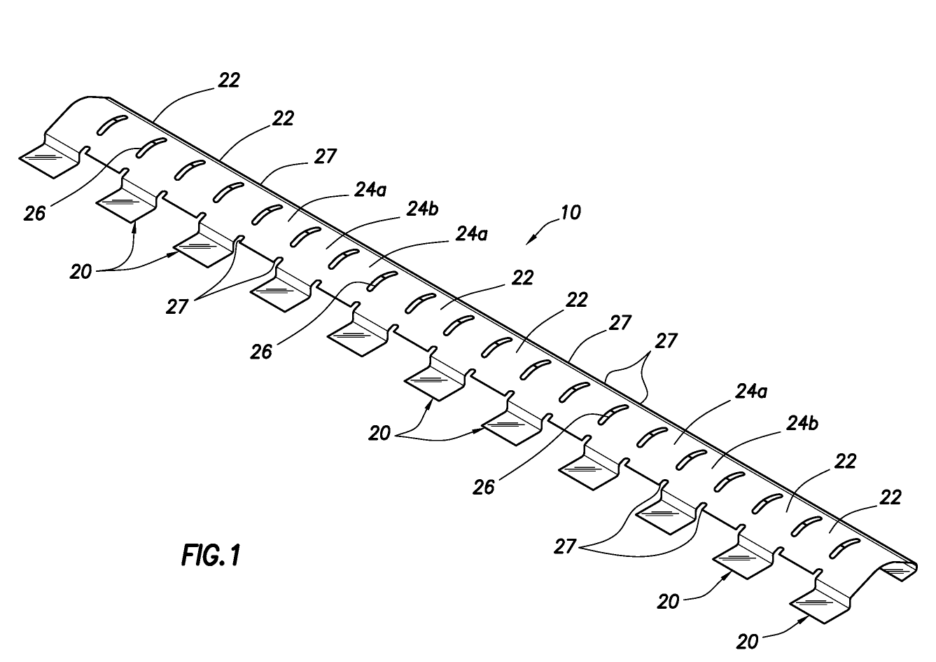

The present invention provides, as illustrated in FIG. 1, electrical grounding apparatus representatively in the form of a specially configured EMI/RFI finger clip gasket structure 10. As later described herein, a gasket structure similar to the gasket structure 10 may be operatively secured to an electrically conductive outer wall portion 12 of, for example, a sheet metal electrical component housing 14 (see FIG. 8) to form an electrical grounding path between the wall portion 12 and an adjacent electrically conductive wall portion 16 of a sheet metal outer housing 18 into which the component housing 14 is inserted. The grounding path formed by the gasket 10 extends across a gap 19 disposed between the electrically conductive wall portions 12,16.

The particular use of the gasket 10 illustrated and described herein is merely representative and principles of this invention are not limited thereto. For example, the gasket 10 could be secured to other types of electrically conductive wall structures, and the gasket 10 could be operatively positioned between other types of electrically conductive wall structures to form an electrical grounding path across a gap therebetween, without departing from principles of the present invention.

In the embodiment thereof representatively illustrated in FIG. 1, EMI/RFI shielding gasket 10 is formed from an elongated thin strip of resiliently deflectable, electrically conductive material such as, for example but not by way of limitation, beryllium-copper or stainless steel. Illustratively, the thickness of the strip material is in the range of from about 0.002″ to about 0.0035″. Gasket 10 is of a longitudinally segmented construction, being defined by a longitudinally spaced series of specially configured clip finger portions 20 interdigitated with a series of spring portions 22. The elongated body 24 of the gasket 10 is divided into interdigitated series of longitudinal body segments 24a,24b by transverse slots 26 formed in the domed portion of the body at the junctures of adjacent pairs of finger portions 20 and spring portions 22, and by spaced series of opposite edge notches 27 formed on the body 24 and aligned with the slots 26.

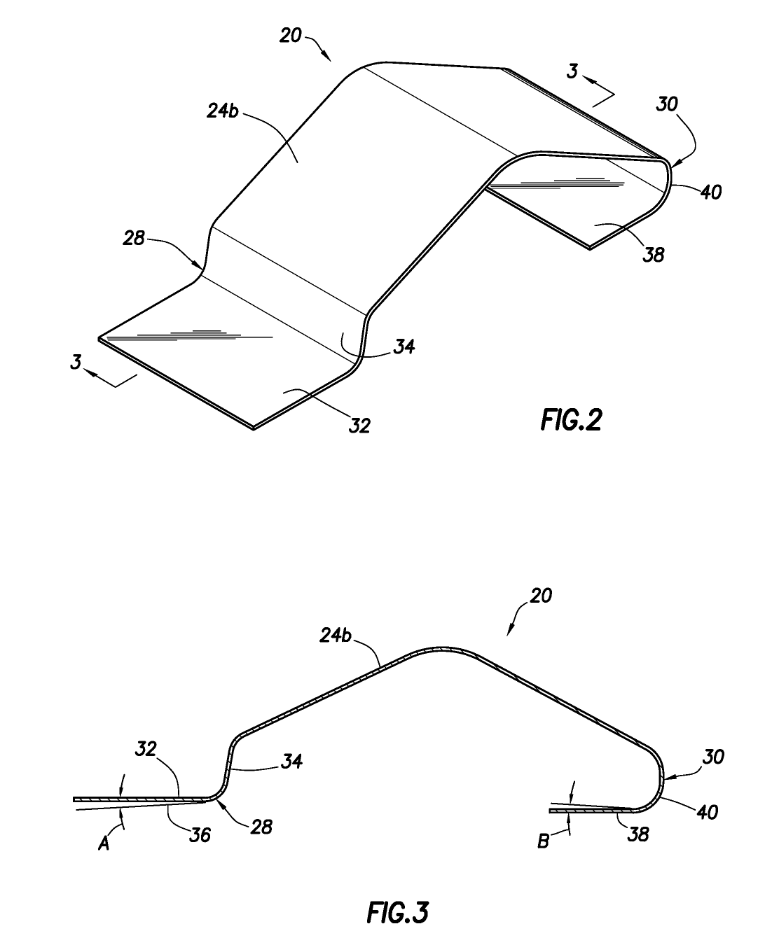

Body 24 (see FIG. 1) has a domed configuration, being laterally bent in an upward direction along its length. Longitudinal body segments 24a define the spring portions 22, while longitudinal body segments 24b form the clip fingers 20 and have differently configured opposite front and rear outer end sections 28,30 (see FIGS. 2 and 3). Representatively, the fingers 20 have substantially constant widths along the lengths of their elongated body segments 24b (which are elongated in a left-to-right direction as viewed in FIG. 3). With continuing reference to FIGS. 2 and 3, the front outer end section 28 of each clip portion 20 includes a generally planar flange portion 32 which projects generally horizontally outwardly from the body segment 24b and is joined thereto by a generally vertically oriented jog portion 34. As shown in FIG. 3, the flange portion 32 is upwardly bent relative to a horizontal reference plane 36 at a small angle A which is representatively about one degree. The rear outer end section 30 of each clip portion 20 has a generally hook-shaped configuration in which a substantially planar outer end portion 38 of the body segment 24b is bent forwardly toward the jog portion 34 beneath a portion of the body segment 24b, and is joined to an overlying wall portion of the body segment 24b by a curved wall portion 40. As shown in FIG. 3, the outer end portion 38 is bent downwardly from the horizontal reference plane 36 at a small angle B which is representatively about two degrees.

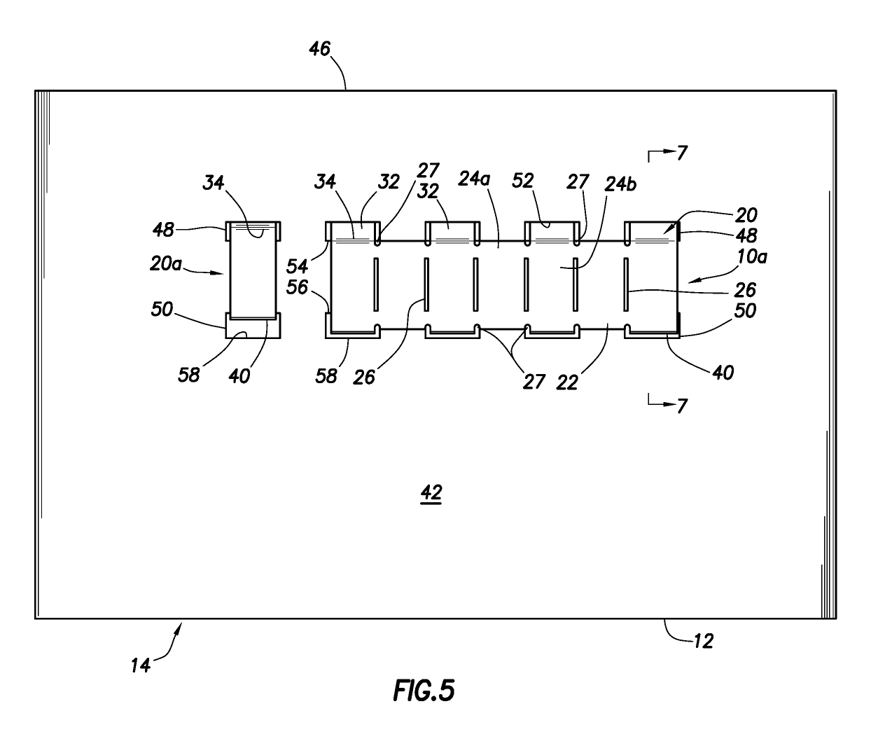

The EMI/RFI finger clip gasket 10 shown in FIG. 1 representatively has eleven clip fingers 20 spaced apart along its length and having configurations which are elongated in directions transverse to the overall length of the gasket 10. The gasket 10 could, of course, be made longer or shorter if required to provide more or fewer fingers to suit the particular electrical grounding application. For example, a shorter finger clip gasket 10a (representatively having four clip finger sections 20) is shown in FIG. 5 next to a single clip finger version 20a of the gasket in which only a clip portion of the gasket structure 10 or 10a is used.

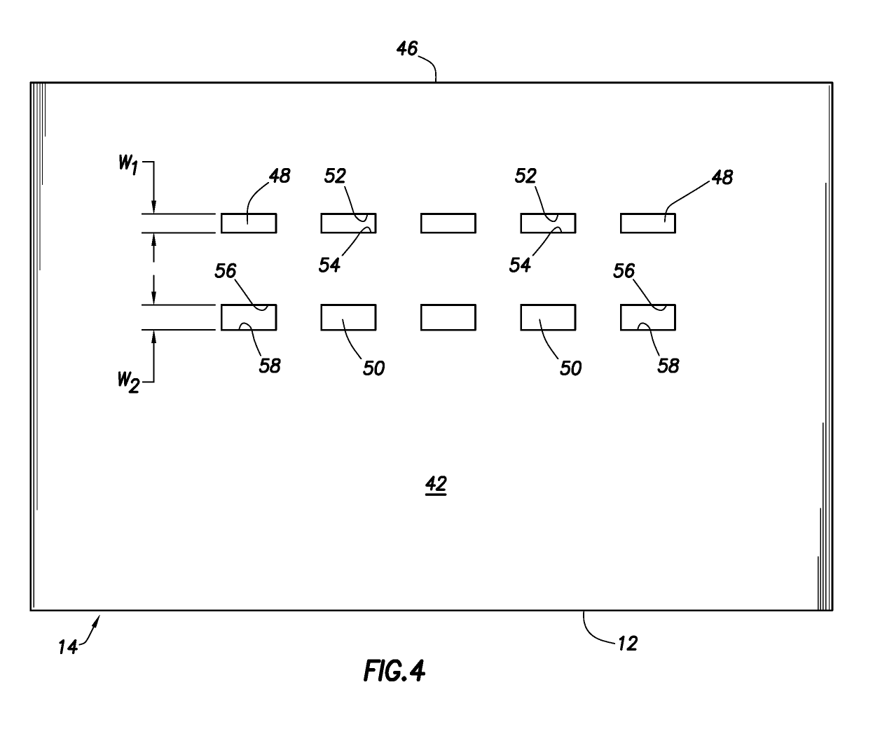

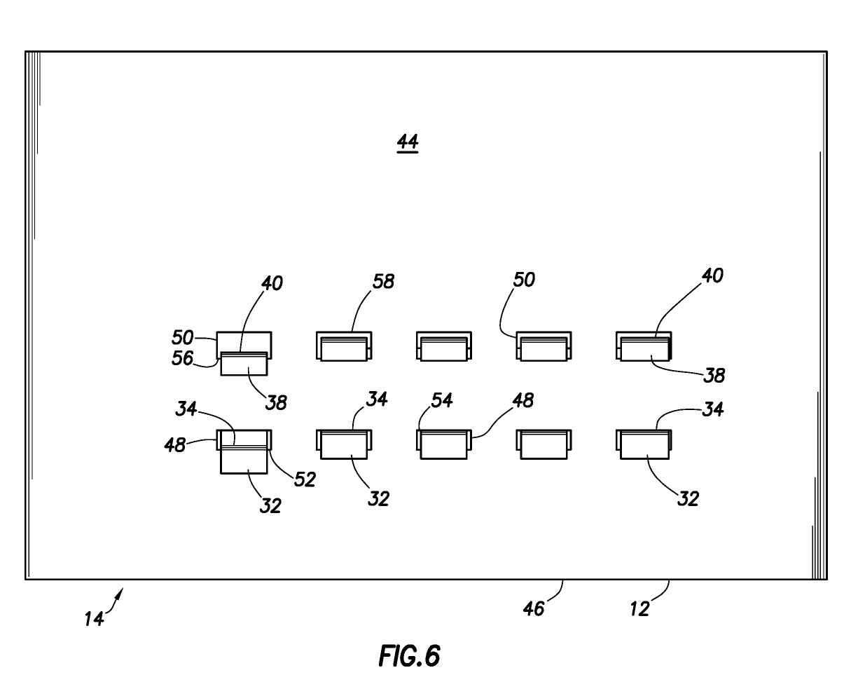

With reference now to FIGS. 4-6, the outer wall portion 12 of the electrical component housing 14 has an outer surface 42 (see FIGS. 4 and 5), an inner surface 44 (see FIG. 6), and front edge 46. Formed in the outer wall portion 12 are a front row of horizontally spaced apart rectangular cutout openings 48 and a rear row of horizontally spaced apart rectangular cutout openings 50 horizontally aligned with the front cutout openings 48. Each front opening 48 has front and rear edges 52 and 54, and each rear opening 50 has front and rear edges 56 and 58. Representatively, each of the front openings 48 has a width W₁, and each of the rear openings 50 has a width W₂ greater than the width W₂. Alternatively, however, width W₁ could be equal to or greater than width W₂ if deemed necessary or desirable.

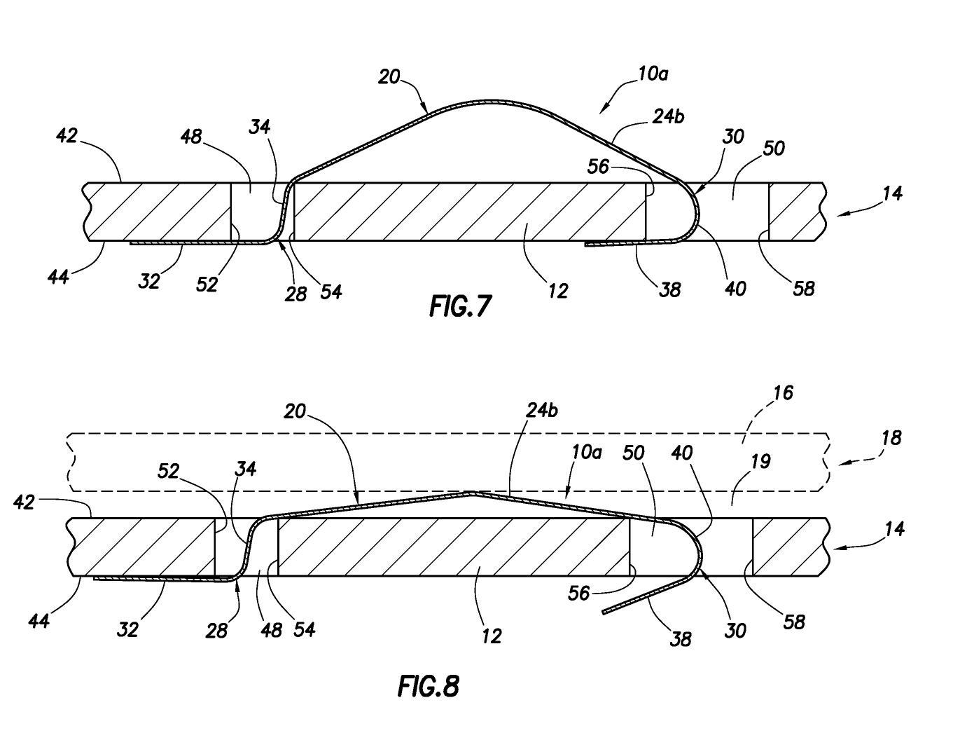

The gasket 10a shown in FIG. 5 may be easily and quickly installed on the outer side surface 42 of the component housing wall 12 by simply inserting the clip finger flange portions 32 into the front wall openings 48 and then inwardly compressing the gasket body 24a toward the outer wall surface 42 to thereby rearwardly move the hooked clip end sections 30 (see FIG. 7) until the outer end portions 38 of the clip end portions 30 snap inwardly into their associated rear cutout openings 50. Inward compression of the body 24a is then terminated to permit the gasket 10a to return to its FIG. 7 relaxed position in which the bottom clip end wall portions 32,38 underlie and engage the inner surface 44 of the component housing wall 12 as shown. A similarly simple method may be utilized to operatively install the gasket 10 shown in FIG. 1 or the single clip finger 20a shown in 5.

With the installed gasket 10a in its FIG. 7 relaxed position, the gasket 10a may be shifted forwardly and rearwardly in its cutout openings 48,50 as may be seen by comparing the rearwardly shifted gasket 10a in FIG. 5 to the forwardly shifted single clip member 20a in FIG. 5. With the gasket 10a rearwardly shifted as shown in FIGS. 5 and 7, the finger jog portions 34 abut the rear edge portions 54 of the front cutout openings 48 and act as stops for preventing front edges of the outer end portions 38 of the hooked clip ends 30 from reaching the front edges 56 of the rear cutout openings 50 to thereby prevent outward movement of the hooked clip ends 30 through the rear cutout openings 50. As can also be seen in FIG. 7, with the jog portions 34 abutting the rear edges 54 of the front cutout openings 48, the flanges 32 also still underlie the inner surface 44 of the wall 12 to thereby prevent inadvertent movement of the front clip ends 28 outwardly through the front cutout openings 48.

Turning now to FIG. 8, when the electrical component housing 14 is operatively inserted into the outer housing 18, the outer housing wall 16 engages the gasket body 24 in a manner downwardly deflecting the gasket 10a to its FIG. 8 compressed position. This compression of the installed gasket 10a causes forward movement of the outer clip end sections 28 relative to their FIG. 7 positions, and also causes rearward movement of the outer clip end sections 30 relative to their FIG. 7 positions. According to an aspect of the present invention, with the gasket 10a in its operatively compressed orientation shown in FIG. 8 forward end portions of the body segments 24b (each of which includes the front clip end section 28) substantially entirely block their associated front cutout areas 48, thereby substantially eliminating entry into or exit from the interior of the component housing 14 of EMI energy via the front cutout openings 48. The use of the specially configured front clip end sections 28 advantageously permits these front cutout openings 48 to be considerably narrower than the rear cutout openings 50. While portions of the rear cutout openings 50 remain unblocked by the finger sections 30, these openings are behind the “seal” area of the compressed gasket 10a (i.e., the area where it contacts the outer housing wall 16) so that transfer of EMI energy through these openings is not an appreciable design concern.

According to another aspect of the present invention, the differently configured outer clip end sections 28,30 provide (compared to conventional “C”-shaped grounding clips) improved grounding edge contact between the overall electrical grounding apparatus (in any of its three representatively illustrated embodiments 10,10a and 20a thereof) and the housing wall 12 on which the grounding apparatus is operatively installed. Specifically, as can be seen in FIG. 8, with the gasket 10a in its operatively compressed position, there are three edge contacts between each clip segment 20 and the wall 12—namely (1) an edge contact between the outer edge of the clip portion 32 (enhanced by the slight upturn of the clip portion 32) and the inner side 44 of the wall 12, (2) an edge contact between a rear edge portion of the front cutout opening 48 and an inner side area of the clip body segment 24b; and (3) an edge contact between a front edge portion of rear cutout opening 50 and an inner side area of the clip body segment 24b.

As can be readily seen from the foregoing, the present invention provides improved EMI/RFI shielding/grounding apparatus which is easy to install, simple and inexpensive to manufacture, provides improved grounding contact between the apparatus and the wall structure on which it is installed, and in a compressed state substantially blocks the wall cutout areas with which ends (representatively forward ends) of its clip finger portions are associated. As used herein, the term EMI is intended to refer to electromagnetic interference and is also intended to be fully synonymous with other similarly used terms of are, including, but not limited to, radio frequency interference (RFI) or radio interference.

The foregoing detailed description is to be clearly understood as being given by way of illustration and example only, the spirit and scope of the present invention being limited solely by the appended claims.

What is claimed is:

1. Electrical grounding apparatus operatively securable to an electrically conductive wall structure having spaced first and second openings therein, said electrical grounding apparatus comprising:
a resiliently deflectable finger clip structure having a generally strip-shaped electrically conductive body with a longitudinally bent central portion and first and second end sections respectively sized and configured to be received and retained in the first and second openings,
said first end section having an outer end portion extending inwardly toward said second end section in a first direction,
said second end section having an outer end portion extending in said first direction away from said first end section, and
said outer end portion of said first end section being generally coplanar with said outer end portion of said second end section.

2. The electrical grounding apparatus of claim 1 wherein:
said first end section has a generally hooked configuration with said outer end portion of said first end section underlying part of said central body portion.

3. The electrical grounding apparatus of claim 2 wherein:
said outer end portion of said first end section is sloped toward said second end section and away from said central body portion.

4. The electrical grounding apparatus of claim 3 wherein:
said outer end portion of said first end section is sloped toward said second end section and away from said central body portion at an angle of approximately two degrees.

5. The electrical grounding apparatus of claim 1 wherein:
said outer end portion of said second end section is offset from said central body portion by a jog section extending generally transversely to said outer end portion of said second end section.

6. The electrical grounding apparatus of claim 1 wherein:
said outer end portion of said second end section is sloped outwardly and toward said central body portion.

7. The electrical grounding apparatus of claim 6 wherein:
said outer end portion of said second end section is sloped outwardly and toward said central body portion at an angle of approximately one degree.

8. The electrical grounding apparatus of claim 1 wherein:
said generally strip-shaped body has a substantially constant width along its length.

9. The electrical grounding apparatus of claim 1 wherein:
said apparatus, when operatively secured to the wall structure, is resiliently deflectable from a relaxed position to a compressed position in which a part of said body substantially blocks one of the first and second openings in the electrically conductive wall structure.

10. The electrical grounding apparatus of claim 9 wherein:
said part of said body includes said second end section thereof.

11. A resiliently deflectable, electrically conductive EMI/RFI finger clip gasket structure operatively securable to an electrically conductive wall structure having parallel rows of longitudinally spaced apart first and second cutout openings therein, said finger clip gasket comprising:
an elongated, laterally bent body portion with opposite first and second side edges and longitudinally interdigitated series of spring and finger clip segments, each of said finger clip segments having first and second end sections respectively positioned adjacent said first and second side edges of said body portion and being respectively receivable and retainable in the first and second cutout openings,
each of said first end sections having an outer end portion extending laterally inwardly in a first direction toward its associated second end section, and
each of said second end sections having an outer end portion extending laterally outwardly in said first direction away from said first end section.
wherein, for each of sadi finger clip segments, said outer end portion of said first end section is generally coplaner with said outer end portion of said second end section.

12. The finger clip gasket structure of claim 11 wherein:
said bent body portion has transverse slots disposed therein in the juncture areas between said spring and finger clip segments.

13. The finger clip gasket structure of claim 11 wherein:
each of said first end sections has a generally hooked configuration with said outer end portion thereof underlying part of said body portion.

14. The finger clip gasket structure of claim 13 wherein:
said outer end portion of each of said first end sections is sloped toward its associated second end section and away from said body portion.

15. The finger clip gasket structure of claim 14 wherein:
said outer end portion of each of said first end sections is sloped toward its associated second section and away from said body portion at an angle of approximately two degrees.

16. The finger clip gasket structure of claim 11 wherein:
said outer end portion of each of said second end sections is offset from said body portion by a jog section extending generally transversely to such outer end portion.

17. The finger clip gasket structure of claim 11 wherein:
said outer end portion of each of said second end section is sloped outwardly and toward said body portion.

18. The finger clip gasket structure of claim 17 wherein:
said outer end portion of each of said second end sections is sloped outwardly and toward said body portion at an angle of approximately one degree.

19. The finger clip gasket structure of claim 11 wherein:
each of said finger clip segments having an elongated, generally strip-shaped body having a substantially constant width along its length.

20. The finger clip gasket structure of claim 11 wherein:
said finger clip gasket structure, when operatively secured to the wall structure, is resiliently deflectable from a relaxed position to a compressed position in which portions of said finger clip segments, including said second end sections thereof, substantially block said second cutout openings

21. Electronic apparatus comprising:
an electrically conductive wall structure having spaced apart first and second openings extending therethrough between first and second opposite sides thereof, and
a resiliently deflectable, electrically conductive grounding structure having a bent body portion disposed on said first side of said wall structure and having opposite first and second end sections respectively received and retained in said first and second openings,
said first end section having an outer end portion extending inwardly in a first direction toward said second end section along said second side of said wall structure and being in a substantially parallel, contacting relationship therewith, and
said second end section having an outer end portion extending outwardly away from said first end section in said first direction along said second side of said wall structure and being in a substantially parallel, contacting relationship therwith.

22. The electronic apparatus of claim 21 wherein:
said second end section includes a jog section transverse to said outer end portion thereof and joining it to said body portion.

23. The electronic apparatus of claim 22 wherein:
said body portion is movable along said first side of said wall structure in said first direction toward and away from said first opening, and
said jog section is cooperatively engageable with a peripheral portion of said second opening in a manner preventing either of said outer end portions from passing outwardly through its associated one of said first and second openings.

24. The electronic apparatus of claim 21 wherein:
said body portion is resiliently deflectable toward said first side of said wall structure in a manner causing part of said body portion, including said second end section, to substantially completely block said second opening.

25. The electronic apparatus of claim 21 wherein:
said wall structure defines an outer wall of an electrically conductive housing structure.

26. Electrical grounding apparatus operatively securable to an electrically conductive wall structure having spaced first and second openings therein, said electrical grounding apparatus comprising:
a resiliently deflectable finger clip structure having a generally strip-shaped electrically conductive body with a longitudinally bent central portion and first and second end sections respectively sized and configured to be received and removably retained in the first and second openings,
said first end section having an outer end portion extending inwardly in a first direction toward said second end section in a first direction,
said second end section having an outer end portion extending in said first direction away from said first end section. and
said outer end portion of said first end section being genera11v coplanar with said outer end portion of said second end section.

27. A resiliently deflectable, electrically conductive EMI/RFI finger clip gasket structure operatively securable to an electrically conductive wall structure having parallel rows of longitudinally spaced apart first and second cutout openings therein, said finger clip gasket comprising:
an elongated, laterally bent body portion with opposite first and second side edges and longitudinally interdigitated series of spring and finger clip segments, each of said finger clip segments having first and second end sections respectively positioned adjacent said first and second side edges of said body portion and being respectively receivable and removably retainable in the first and second cutout openings,
each of said first end sections having an outer end portion extending laterally inwardly in a first direction toward its associated second end section and
each of said second end sections having an outer end portion extending laterally outwardly in said first direction away from said first end section. and
wherein, for each of said finger clip segments. said outer end portion of said first end section is genera11y coplanar with said outer end portion of said second end section.

28. Electronic apparatus comprising:
an electrically conductive wall structure having spaced apart first and second openings extending therethrough between first and second opposite sides thereof and
a resiliently deflectable, electrically conductive grounding structure having a bent body portion disposed on said first side of said wall structure and having opposite first and second end sections respectively received and removably retained in said first and second openings,
said first end section having an outer end portion extending inwardly toward said second end section along said second side of said wall structure and being in a substantially parallel. contacting relationship therewith, and
said second end section having an outer end portion extending outwardly away from said first end section in said first direction along said second side of said wall structure and being in a substantially parallel. contacting relationship therewith.
